(19) United States
(12) Patent Application Publication
(10) Pub. No.: US 2026/0016520 A1
(43) Pub. Date: Jan. 15, 2026

(54) MEASUREMENT APPLICATION DEVICE AND METHOD

(71) Applicant: Rohde & Schwarz GmbH & Co. KG, München (DE)

(72) Inventor: Bruno SCHEFFOLD, Berkheim (DE)

(21) Appl. No.: 18/772,515

(22) Filed: Jul. 15, 2024

(51) Int. Cl. G01R 23/167

(52) U.S. Cl. CPC G01R 23/167

(57) ABSTRACT

A measurement application device includes at least one signal port, at least one measurement unit coupled to the at least one signal port, wherein the at least one measurement unit is configured to process an incoming signal received via the at least one signal port based on at least one of a predefined resolution bandwidth and a predefined video bandwidth, and a signal processor coupled to the at least one measurement unit, wherein the signal processor is configured to determine at least one of the resolution bandwidth and the video bandwidth for the at least one measurement unit based on at least one of a maximum signal level to be measured, and a minimum signal level to be measured. Further, the present disclosure provides a respective method.

### TECHNICAL FIELD

The disclosure relates to a measurement application device and a respective method.

### BACKGROUND

Although applicable to any type of measurement application device, the present disclosure will mainly be described in conjunction with signal analyzers, like spectrum analyzers.

When analyzing signals e.g., during development of electronic systems, the user performs a manual approach to finding the optimal settings for the respective signal analyzer and the respective measurement task. This manual approach is, however, time consuming and error prone.

Accordingly, there is a need for improving signal analysis.

### SUMMARY

The above stated problem is solved by the features of the independent claims. It is understood, that independent claims of a claim category may be formed in analogy to the dependent claims of another claim category.

Accordingly, it is provided:

A measurement application device comprising at least one signal port, at least one measurement unit coupled to the at least one signal port, wherein the at least one measurement unit is configured to process an incoming signal received via the at least one signal port based on at least one of a predefined resolution bandwidth and a predefined video bandwidth, and a signal processor coupled to the at least one measurement unit, wherein the signal processor is configured to determine at least one of the resolution bandwidth and the video bandwidth for the at least one measurement unit based on at least one of a maximum signal level to be measured, and a minimum signal level to be measured.

Further, it is provided:

A method for operating a measurement application device, the method comprising receiving an incoming signal, processing the incoming signal based on at least one of a predefined resolution bandwidth and a predefined video bandwidth, and determining at least one of the resolution bandwidth and the video bandwidth based on at least one of a maximum signal level to be measured, and a minimum signal level to be measured.

The present disclosure is based on the finding that manually configuring a measurement application device, like a signal or spectrum analyzer, usually is a manual, time-consuming, and error-prone task.

Depending on the actual measurement task, a user is required to manually identify the most appropriate settings for parameters, like the resolution bandwidth and the video bandwidth, of the measurement application device for a specific measurement task. If multiple measurements are required e.g., for performing measurements that confirm the conformity of a device under test, also called DUT, to respective standards or regulations, the user is required to determine multiple settings for the measurement application device manually.

Further, for different measurement application devices, the settings may be different. If a set of parameters is e.g., stored for automating specific test measurements, and a new generation of the measurement application device is introduced, the parameters need to be readjusted for this new generation of measurement application device.

The present disclosure, therefore, provides a solution that allows automatically determining parameters for a measurement application device, like a signal or spectrum analyzer.

To this end, the present disclosure provides the measurement application device with at least one signal port for receiving an incoming signal e.g., from a DUT. The measurement application device further comprises at least one measurement unit that is coupled to the at least one signal port. Generally, one signal port is coupled to one measurement unit. If multiple signal ports are provided, a single measurement unit may be provided for each one of the signal ports, or a single measurement unit may comprise parallel signal paths, one per signal port, comprising the same elements as described herein for the measurement unit.

The measurement unit may process the incoming signal based on at least one of a predefined resolution bandwidth and a predefined video bandwidth. The terms “resolution bandwidth” and “video bandwidth” are to be understood as the resolution bandwidth and the video bandwidth generally referred to in the field of signal analyzers, especially spectrum analyzers. The resolution bandwidth, and the video bandwidth are examples of parameters of measurement application devices that are usually set by the user manually in an iterative process.

The measurement application device further comprises a signal processor that is coupled to the at least one measurement unit. The signal processor performs the determination of at least one of the resolution bandwidth and the video bandwidth for the at least one measurement unit based on at least one of a maximum signal level to be measured, and a minimum signal level to be measured.

In embodiments, a single signal processor may be provided for and coupled to a plurality of measurement units. In such embodiments, the signal processor may perform all functions described herein for a single measurement unit also individually for each one of the plurality of measurement units.

In the field of signal or spectrum analyzers, the resolution bandwidth directly determines the duration of a measurement. It is, therefore, desirable to optimize the resolution bandwidth such that the duration of the measurement is minimized, and that the accuracy of the measurement is as high as required for the respective measurement task. This is, especially, beneficial for automated test sequences that involve a plurality of consecutive measurements on a plurality of devices under test.

The maximum signal level to be measured, and the minimum signal level to be measured characterize the measurement task to be performed with measurement application devices, like signal or spectrum analyzers, in detail. Consequently, with at least one of these parameters, the signal processor may automatically determine at least one of a resolution bandwidth and a video bandwidth for the processing of the respective incoming signal.

If for example, a specific measurement tolerance is to be achieved with a measurement, the minimum signal level to be measured may be determined based on the tolerance prior to performing the measurement. Further, depending on the type of measurement, the minimum signal level to be measured may e.g., depend on the tolerance and the maximum signal level to be measured, or vice versa.

Consequently, by using the maximum signal level to be measured, and the minimum signal level to be measured as input values for the signal processor, the signal processor may determine optimum values for the at least one of the predefined resolution bandwidth and the predefined video bandwidth.

The maximum signal level to be measured is the level that can be measured at most with a specific configuration of the measurement application device. Accordingly, the attenuator may be set according to the maximum signal level to be measured. In an exemplary application, the user may specify that a signal with a maximum level of 0 dBm is to be measured. A signal with 10 dBm would then be “clipped”. In other words, the respective analog-to-digital converter is fully driven by a 0 dBm signal (all bits are 1). The user may, for example, state that a minimum signal level to be measured is-50 dBm. Accordingly, the resolution bandwidth may be adjusted, which in turn affects the measurement time. A large resolution bandwidth (e.g., 10 kHz, 100 kHz) means a shorter measurement time but also a lower signal-to-noise ratio, also called SNR, for lower signal levels, while a small resolution bandwidth (e.g., 10 Hz) means a longer measurement time but also a higher SNR for lower signal levels.

A measurement application device according to the present disclosure may comprise any device that may be used in a measurement application to acquire an input signal or to generate an output signal, or to perform additional or supporting functions in a measurement application. A measurement application device may also comprise or be implemented as program application or program applications, also called measurement program application or measurement program applications, that may be executed on a computer device and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. Such electric, magnetic, or electromagnetic measurements may e.g., be performed in a measurement laboratory or in a production facility in the respective production line. An exemplary measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters. In embodiments, the signal acquisition is performed via the signal acquisition section in a wired or contact-based manner or fashion. To this end, a respective measurement probe may be coupled to the measurement application device via a respective cable. In embodiments, the signal generation and emission is performed via the signal generation section in a wired or contact-based manner or fashion. To this end, a respective signal output probe may be coupled to the measurement application device via a respective cable, or the signal may be output directly via the cable e.g., to a device under test.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

The signal processor may comprise or may be provided in or as part of at least one of a dedicated processing element e.g., a processing unit, a microcontroller, a field programmable gate array, FPGA, a complex programmable logic device, CPLD, an application specific integrated circuit, ASIC, or the like. A respective program or configuration may be provided to implement the required functionality. The signal processor may at least in part also be provided as a non-transitory computer program product comprising computer readable instructions that may be executed by a processing element. In a further embodiment, the signal processor may be provided as addition or additional function or method to the firmware or operating system of a processing element that is already present in the respective application as respective computer readable instructions. Such computer readable instructions may be stored in a memory that is coupled to or integrated into the processing element. The processing element may load the computer readable instructions from the memory and execute them. The same applies to any other element, unit or function disclosed herein as part of the measurement application device.

In addition, it is understood, that any required supporting or additional hardware may be provided like e.g., a power supply circuitry and clock generation circuitry.

Generally, any computer program or computer program product disclosed herein is to be understood as a non-transitory computer program product.

With the solution of the present disclosure, the usage of a measurement application device, especially the configuration of the measurement application device, may be simplified. Especially for multiple automated consecutive measurements the time for setting up the measurement application may be reduced.

Possible exemplary measurement tasks to be performed with a measurement application device according to the present disclosure comprise, but are not limited to, spurious free dynamic range measurements, and characterizing a DUT with a predetermined measurement accuracy e.g., influenced by statistical noise.

The measurement accuracy may e.g., be provided as “Cpk” value. Cpk refers to the “process capability index”, and is a standard term describing the capability of a measurement or validation process. Especially for an automatic resolution or video bandwidth setting the cpk may be used for testing against a predefined tolerance level. Further details are provided below in conjunction with the artificial-intelligence-based algorithm.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, the at least one measurement unit may comprise at least one input port, each input port being coupled to one signal port, an attenuator for each input port, wherein the attenuator is coupled to the respective input port, a local oscillator e.g., a DDS oscillator, a mixer for each attenuator, wherein the mixer is coupled to the local oscillator and the respective attenuator, a filter for each mixer, wherein the filter is coupled to the respective mixer, and a signal analyzer for each filter, wherein the signal analyzer is coupled to the respective filter, and wherein the signal analyzer is configured to determine at least an amplitude of the respective incoming signal, and to provide the determined amplitude to the signal processor.

The measurement unit may in embodiments comprise the elements of a signal path of a spectrum analyzer. The measurement unit may, consequently, comprise an input port for each signal port to couple to the respective signal port, an attenuator for each input port, a mixer coupled to the attenuator, and a local oscillator coupled to the mixer. The mixer may be coupled to a filter, and the filter may be coupled to a signal analyzer.

It is understood, that the signal path described above is an example, and that the signal path may comprise further elements, or that some elements may be omitted in other embodiments.

The attenuator may attenuate a signal level of the incoming signal received from the respective signal port via the respective input port. The local oscillator provides the oscillator signal for the mixer that mixes the oscillator signal with the attenuated signal received from the attenuator, and provides a respective intermediate frequency signal.

The term “local oscillator” comprises any adequate type of oscillator. In embodiments, the local oscillator may comprise a Direct Digital Synthesis oscillator, also called DDS oscillator.

In embodiments that may be combined with any other embodiment disclosed herein, a filter e.g., a band-pass filter may be provided between the attenuator and the mixer. Such a band-pass filter may serve to e.g., filter out unwanted image frequencies.

The filter that receives the signal from the mixer, also called intermediate frequency signal, may be seen as kind of frequency resolution-based filter, as they may be present in spectrum analyzers. The filter may comprise a single filtering element, or a plurality of filter stages with different filter ranges.

The analysis unit may digitize the signal received from the filter, and perform the determination of the amplitude of the filtered signal.

In another embodiment, which can be combined with all other embodiments mentioned above or below, the signal processor may be further configured to determine at least one of the maximum signal level to be measured, and the minimum signal level to be measured based on the determined signal amplitude.

The signal amplitude provides the maximum signal level to be measured, and the minimum signal level to be measured, especially if provided together with a reference signal level, which the analysis unit may also provide.

The signal amplitude alone may, therefore, be sufficient for the signal processor to determine the at least one of the predefined resolution bandwidth and the predefined video bandwidth.

If for example, a minimum signal level of −50 dBm with sufficient SNR may reliably be determined with a resolution bandwidth of 100 Hz, there is no need to lower the resolution bandwidth to 10 Hz.

In a further embodiment, which can be combined with all other embodiments mentioned above or below, the signal processor may be further configured to determine at least one of the maximum signal level to be measured, and the minimum signal level to be measured based further on a signal level of a signal provided by the local oscillator.

In general, with a high local oscillator level, a higher sensitivity, i.e., less noise, is present to detect low RF-signal levels. If high dynamic-range for detecting low-level signals in the presence of high-level signals nearby is required, it is better to decrease the local oscillator level to avoid intermodulation-distortion within the mixer. Therefore, it may be necessary to optimize the local oscillator level depending on the measurement task. The local oscillator level may, consequently, be an input for the below-mentioned determination algorithm.

In another embodiment, which can be combined with all other embodiments mentioned above or below, the signal processor may be further configured to set a signal level of a signal provided by the local oscillator based on a predetermined spurious free dynamic range for the mixer.

For example, a quick sweep of the selected frequency range could be performed to determine the highest signal level, then the appropriated local oscillator level could be selected to assure the best sensitivity possible without risking intermodulation. This selection of the local oscillator level could also be performed by the determination algorithm.

While above, the signal level of the signal provided by the local oscillator and the spurious free dynamic range are provided as examples, other parameters may also be taken into account by the signal processor.

Such further parameters may include, but are not limit to, at least one of a mixer conversion factor, also known as the conversion gain or conversion loss, temperature drifts, calibration data, and device specific or individual parameters.

In a further embodiment, which can be combined with all other embodiments mentioned above or below, the signal processor may be further configured to set a filter bandwidth for the filter in order to set the at least one of the resolution bandwidth and the video bandwidth.

In embodiments with a filter in the signal chain, the resolution bandwidth may be influenced or set by setting the filter bandwidth. This provides for a simple signal path, and a simple configuration of the resolution bandwidth.

In another embodiment, which can be combined with all other embodiments mentioned above or below, the signal analyzer may comprise at least one of a peak detector and a Fast Fourier Transformation unit.

The peak detector is a simple element that may be used to perform a signal amplitude detection, and in embodiments also a spectrum analysis, of the incoming signal after attenuating, mixing, and filtering the incoming signal. In other embodiments, the Fast Fourier Transformation unit may also determine peak signal levels, and therefore, the amplitude of the incoming signal.

In a further embodiment, which can be combined with all other embodiments mentioned above or below, the signal processor may be further configured to set a bandwidth for the Fast Fourier Transformation unit in order to set the at least one of the resolution bandwidth and the video bandwidth.

In embodiments, where a Fast Fourier Transformation unit is used to perform peak level or amplitude detection, or a signal or spectrum analysis, the bandwidth of the Fast Fourier Transformation may be set by the signal processor.

In another embodiment, which can be combined with all other embodiments mentioned above or below, the signal processor may be further configured to set an attenuation level of the attenuator in order to set the at least one of the resolution bandwidth and the video bandwidth.

The signal processor may automatically set the attenuation level of the attenuator according to a maximum signal level or amplitude of the incoming signal. The attenuation level may be set such that all elements following the attenuator may correctly process the incoming signal as required.

In a further embodiment, which can be combined with all other embodiments mentioned above or below, the signal processor may be configured to determine the at least one of the resolution bandwidth and the video bandwidth such that the measurement time is minimized.

As indicated above, the measurement time depends on the resolution bandwidth, as well as the SNR of the measurement results.

While the measurement may require a specific SNR, that leads to a specific measurement duration, the signal processor may limit the resolution bandwidth to the required amount, without further reducing the resolution bandwidth. This will ensure that the measurement may be performed as quickly as possible.

In another embodiment, which can be combined with all other embodiments mentioned above or below, the measurement application device may further comprise at least one of a user input interface and a control interface. The at least one of the user input interface and the control interface may be configured to receive at least one of the maximum signal level and the minimum signal level, and to forward the received at least one of the maximum signal level and the minimum signal level to the signal processor.

The two types of interfaces named above serve two purposes. The user input interface may serve for a user to control the measurement application device e.g., to input the at least one of the maximum signal level and the minimum signal level.

The control interface also serves for controlling the measurement application device, and e.g., to provide the at least one of the maximum signal level and the minimum signal level. However, the control interface may be used to control the measurement application device via other devices that communicatively couple to the control interface. This allows e.g., performing automated test runs.

In another embodiment, which can be combined with all other embodiments mentioned above or below, the signal processor may comprise a look-up table that maps the at least one of the maximum signal level and the minimum signal level to at least one of the resolution bandwidth and the video bandwidth.

A look-up table is a simple way of allowing the signal processor to determine the at least one of the resolution bandwidth and the video bandwidth.

In embodiments, the look-up table may also comprise more input parameters than the maximum signal level and the minimum signal level. The content of the look-up tables may be determined experimentally e.g., by the manufacturer of the measurement application device.

In a further embodiment, which can be combined with all other embodiments mentioned above or below, the signal processor may comprise a processing unit configured to execute a determination algorithm that may determine at least one of the resolution bandwidth and the video bandwidth for the at least one of the maximum signal level and the minimum signal level.

The determination algorithm may comprise any adequate type of algorithm that allows determining the at least one of the resolution bandwidth and the video bandwidth based on at least one of the maximum signal level and the minimum signal level.

In another embodiment, which can be combined with all other embodiments mentioned above or below, the determination algorithm may comprise an artificial-intelligence-based algorithm.

The cpk value or cpk index mentioned above, in the context of the present disclosure may represent the distance between the measured value and a respective tolerance-line (pass-criterion) in units of the standard-deviation (=measurement uncertainty caused by statistical noise in a gaussian shape). By decreasing the resolution bandwidth, the measurement uncertainty is decreased, and therefore, the probability of a wrong pass-results is also decreased. Vice versa, if measurement uncertainty is too high, the capability of the measurement process is low, because a pass signal if the tolerance line is close or even within the statistical distribution of noise may not be reliably provided.

The cpk value of a measurement process represents the reliability of the pass- or fail-result in the presence of a measured signal-level. So if the measured signal level is close to the tolerance-level the resolution bandwidth should be reduced in order to reduce noise and assure that measurement uncertainty is low. If a measured signal level is far away from a given tolerance level, the measurement time may be shortened because a higher measurement uncertainty is sufficient for a reliable pass (-or fail) result.

Consequently, the artificial-intelligence-based algorithm may be set to adapt the resolution and/or video bandwidth accordingly. If a frequency sweep is performed e.g., against a constant tolerance level, a low-resolution bandwidth default-setting could be chosen for a start, and the resolution bandwidth could be reduced during the next frequency steps of the sweep, depending on the distance between the measured values and tolerance-line. The higher the cpk is chosen for the respective measurement task, the harder is the requirement on the reliability of the pass/fail-result of the measurement. Therefore, the influence of noise needs to be reduced with higher cpk values, and the longer the measurement time will be and vice versa.

The artificial-intelligence-based algorithm may comprise any adequate type of algorithm. Since the different contributions of the resolution bandwidth and/or the video bandwidth, the local oscillator level, the switchable attenuation level in the RF-path of the signal analyzer, and their influences on the displayed average noise level are predictable (e.g. decrease of RBW by: 10 will decrease Noise-Level by −10 dB) the algorithm may be determined theoretically and may be realized using a respective design-model. For example, the noise level at one predefine setting may be known, e.g. attenuator=0 dB, local oscillator level=maximum, and resolution bandwidth and/or video bandwidth=1 kHz, a respective

Therefor training of the artificial-intelligence-based algorithm may be performed by a “self-characterization”: when the signal analyzer is in standby (switched on, but not used by the operator), the signal-processor may terminate the RF-input, e.g., by a 50 Ohm standard, and may measure the internal displayed average noise level as a reference and as a function of the analyzed input frequency. This information may be used as training data. Such data is especially useful to characterize the different noise-levels in the different rf-signal paths used for the different frequency ranges of the signal analyzer (depending of design, but also aging) and use it as a starting point to calculate the noise behavior when changing the resolution bandwidth and/or video bandwidth, the local oscillator settings, and the RF-attenuator settings.

In a further embodiment, which can be combined with all other embodiments mentioned above or below, the signal processor may be further configured to receive a plurality of sets comprising at least one of a maximum signal level to be measured, and a minimum signal level to be measured for a specific frequency range. The signal processor may be further configured to determine the at least one of the resolution bandwidth and the video bandwidth for each set based on the at least one of a maximum signal level to be measured, and a minimum signal level to be measured provided in the respective set.

In some measurement applications, multiple measurements may need to be performed in an automated test procedure for different combinations of maximum signal levels to be measured, and minimum signal levels to be measured at different frequencies.

By enabling the signal processor to receive multiple parameters sets, it is easily possible to prepare a complex measurement in advance and have the signal processor determine all required parameters in advance.

In another embodiment, which can be combined with all other embodiments mentioned above or below, the measurement application device may further comprise a display coupled to the signal processor, wherein the signal processor may be configured to display at least one of different resolution bandwidths and different video bandwidths for different frequency ranges.

The display may be any kind of display that may be integrated into or coupled to the measurement application device. Such a display may also comprise a web server, dedicated or integrated into the measurement application device, that shows the respective data on a website or web-page.

The signal processor may use the display to show the determined at least one of the resolution bandwidth and the video bandwidth, especially for different frequency ranges. Just as an example, the display may show a resolution bandwidth of 1 Hz from 0 Hz to 1 GHz, a resolution bandwidth of 100 Hz from 1 GHz to 10 GHz, and a resolution bandwidth of 10 kHz from 10 GHz to 30 GHz.

In a further embodiment, which can be combined with all other embodiments mentioned above or below, the signal processor may be further configured to receive an indication of a signal type of the incoming signal. The signal processor may be further configured to automatically determine the at least one of the resolution bandwidth and the video bandwidth for different frequency ranges based on the signal type.

Different signal types may comprise, but are not limited to, a modulated AM signal, a modulated FM signal.

For different types of signals at least parts of the signals may require different resolution bandwidths and video bandwidths. For example, the sidebands of different signal types may require specific resolution bandwidths and video bandwidths.

The different frequency ranges may be used in “high-level” applications of the measurement application device, e.g., for detecting the type of signal (e.g. AM or FM modulated signal).

In another further embodiment, which can be combined with all other embodiments mentioned above or below, the signal processor may be further configured to determine the signal type of the incoming signal, and use the determined signal type as received indication of the signal type.

In embodiments, the signal type may automatically be determined by the signal processor. To this end, the signal processor may execute a respective algorithm.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a measurement application device according to the present disclosure;

FIG. 2 shows a block diagram of another embodiment of a measurement application device according to the present disclosure;

FIG. 3 shows a block diagram of another embodiment of a measurement application device according to the present disclosure;

FIG. 4 shows a block diagram of another embodiment of a measurement application device according to the present disclosure;

FIG. 5 shows a block diagram of another embodiment of a measurement application device according to the present disclosure;

FIG. 6 shows a block diagram of another embodiment of a measurement application device according to the present disclosure;

FIG. 7 shows a block diagram of another embodiment of a measurement application device according to the present disclosure;

FIG. 8 shows a block diagram of another embodiment of a measurement application device according to the present disclosure;

FIG. 9 shows a flow diagram of an embodiment of a method according to the present disclosure;

FIG. 10 shows a block diagram of another embodiment of a measurement application device according to the present disclosure; and

FIG. 11 shows a block diagram of another embodiment of a measurement application device according to the present disclosure.

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

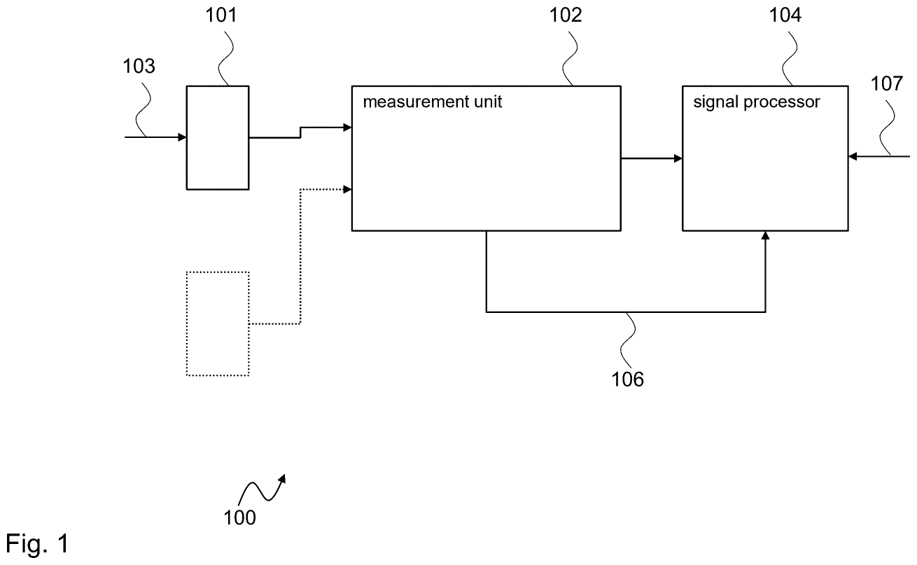

FIG. 1 shows a measurement application device 100. The measurement application device 100 comprises a signal port 101 that is coupled to a measurement unit 102. More possible signal ports that may be coupled to the measurement unit 102 are hinted at by a dotted signal port. The measurement unit 102 is coupled to a signal processor 104. The signal port 101 serves for receiving an incoming signal 103 that is to be analyzed. The explanations provided herein for any of the embodiments of the measurement application device apply mutatis mutandis to the measurement application device 100.

The incoming signal 103 is provided to the measurement unit 102 that processes the incoming signal 103 based on at least one of a predefined resolution bandwidth and a predefined video bandwidth. The measurement unit 102 may e.g., perform the signal processing or analysis that is required in a signal or spectrum analyzer. Such an analysis may usually be configured. Parameters for configuring this analysis may comprise the resolution bandwidth and/or the video bandwidth 106. In embodiments, the measurement unit 102 may be the measurement signal path of a signal analyzer or a spectrum analyzer.

The signal processor 104 may determine at least one of the resolution and/or video bandwidth 106 for the measurement unit 102 based on at least one of a maximum and a minimum signal level to be measured 107.

As mentioned above and shown in other figures, the maximum and/or minimum signal levels 107 to be measured may be provided to the signal processor 104 e.g., by a user, by other measurement application devices, or via the signal amplitude of the incoming signal 103.

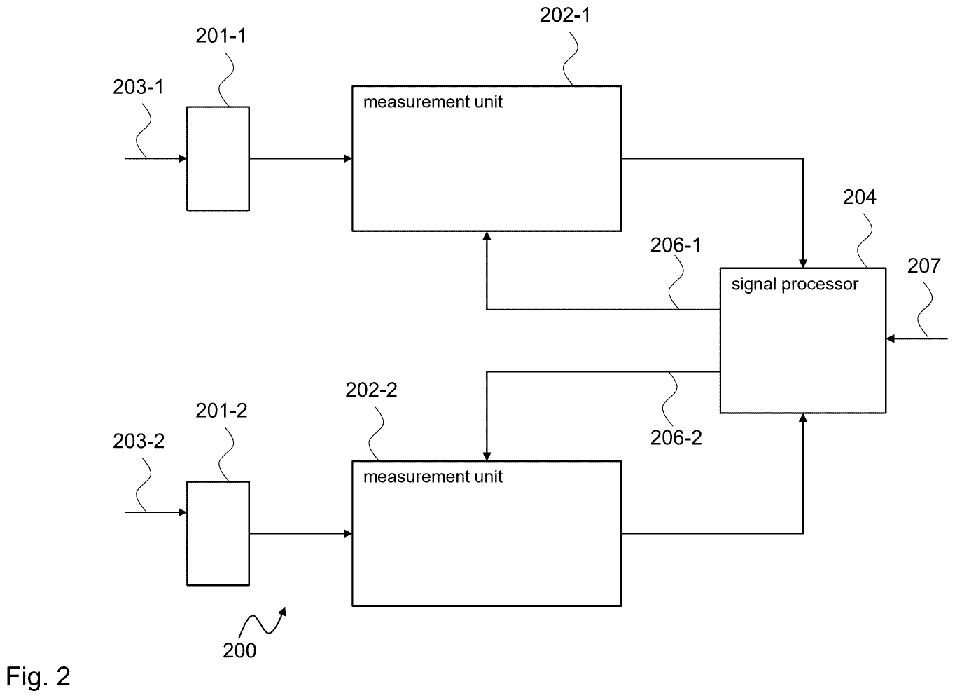

FIG. 2 shows a measurement application device 200. The measurement application device 200 is based on the measurement application device 100. Consequently, the measurement application device 200 comprises a signal port 201-1 that is coupled to a measurement unit 202-1. The measurement unit 202-1 is coupled to a signal processor 204. The signal port 201-1 serves for receiving an incoming signal 203-1 that is to be analyzed. The explanations provided herein for any of the embodiments of the measurement application device apply mutatis mutandis to the measurement application device 200.

In addition, the measurement application device 200 comprises a second signal port 201-2 that serves for receiving a second incoming signal 203-2. The second signal port 201-2 is coupled to a second measurement unit 202-2, and the measurement unit 202-2 is coupled to a signal processor 204.

The signal processor 204, consequently, determines the resolution and/or video bandwidth 206-1 for the first measurement unit 202-1, and the resolution and/or video bandwidth 206-2 for the second measurement unit 202-2.

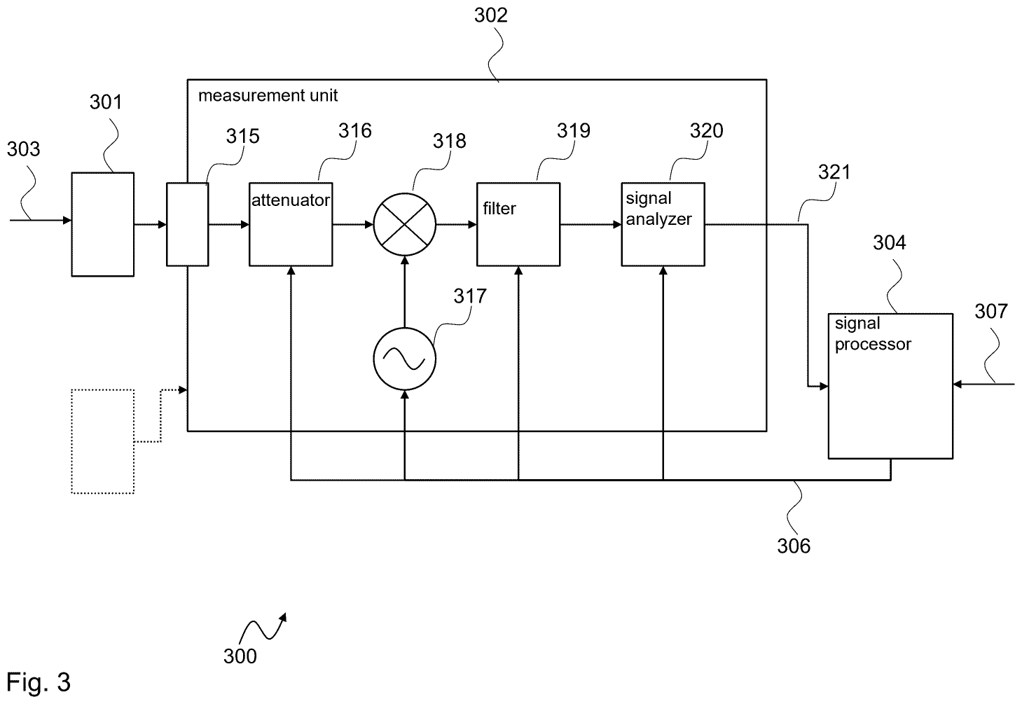

FIG. 3 shows a measurement application device 300. The measurement application device 300 is based on the measurement application device 100. Therefore, the measurement application device 300 comprises a signal port 301 that is coupled to a measurement unit 302. The measurement unit 302 is coupled to a signal processor 304. The signal port 301 serves for receiving an incoming signal 303 that is to be analyzed. The explanations provided herein for any of the embodiments of the measurement application device apply mutatis mutandis to the measurement application device 300.

In the measurement application device 300, the measurement unit 302 is shown in more detail in an exemplary embodiment. The measurement unit 302 comprises an input port 315 that is externally coupled to the signal port 301. Internally, the input port 315 is coupled to attenuator 316. The attenuator 316 and a local oscillator 317 are both coupled to a mixer 318. The mixer 318 is coupled to a filter 319, and filter 319 is coupled to a signal analyzer 320. The signal analyzer 320 determines at least an amplitude of the incoming signal 303, and provides the determined amplitude 321 to the signal processor 304. As already indicated above, in embodiments, additional elements may be provided in the signal chain or path between input port 315 and signal analyzer 320.

In case that multiple signal ports are provided, the full signal chain or path as described above for a single signal port 301 may be provided for each one of the signal ports. In embodiments, the single signal chains or paths may also share components, like the signal analyzer 320.

The determined amplitude 321 may be provided to the signal processor 304 as digital data value or as analog signal, depending on the embodiment of the signal processor 304.

The signal processor 304 may provide the resolution and/or video bandwidth 306 in different forms of control data or parameters. The signal processor 304 may e.g., control the attenuator 316, the local oscillator 317, the filter 319, or the signal analyzer 320 with respective parameters in order to set the required resolution and/or video bandwidth 306.

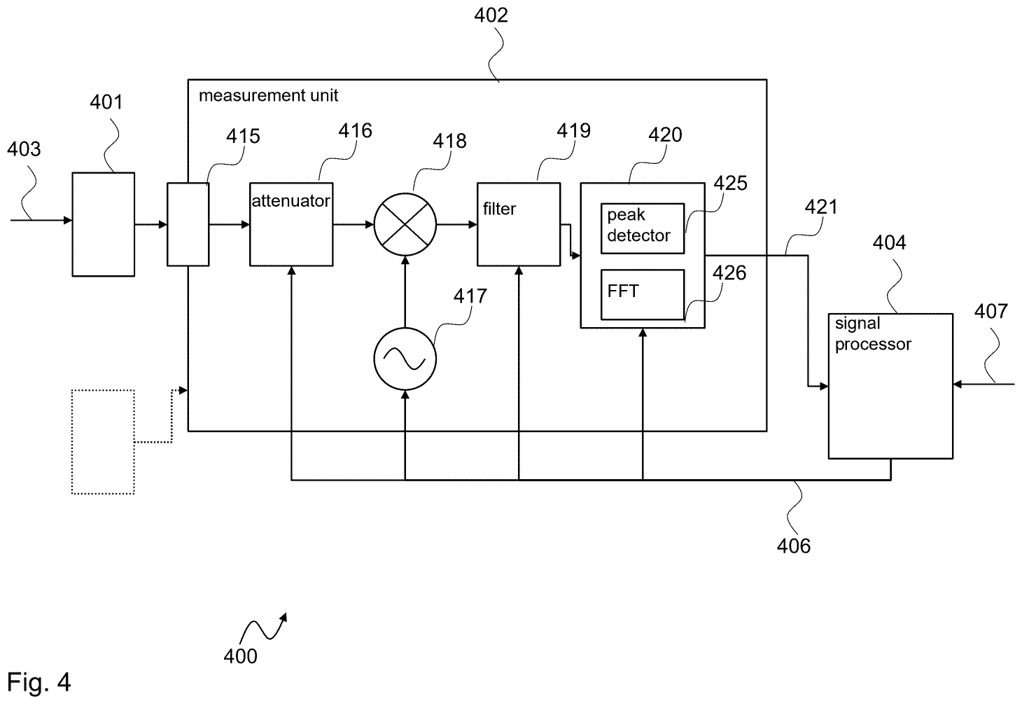

FIG. 4 shows a measurement application device 400. The measurement application device 400 is based on the measurement application device 300. Therefore, the measurement application device 400 comprises a signal port 401 that is coupled to a measurement unit 402. The measurement unit 402 is coupled to a signal processor 404. The signal port 401 serves for receiving an incoming signal 403 that is to be analyzed. The measurement unit 402 comprises an input port 415 that is externally coupled to the signal port 401. Internally, the input port 415 is coupled to attenuator 416. The attenuator 416 and a local oscillator 417 are both coupled to a mixer 418. The mixer 418 is coupled to a filter 419, and filter 419 is coupled to a signal analyzer 420. The signal analyzer 420 determines at least an amplitude of the incoming signal 403, and provides the determined amplitude 421 to the signal processor 404. As already indicated above, in embodiments, additional elements may be provided in the signal chain or path between input port 415 and signal analyzer 420. The explanations provided herein for any of the embodiments of the measurement application device apply mutatis mutandis to the measurement application device 400.

In the measurement application device 400, the signal analyzer 420 comprises a peak detector 425 for determining the amplitude of the incoming signal 403. The signal analyzer 420 further comprises a Fast Fourier Transform unit 426. The Fast Fourier Transform unit 426 may in embodiments be provided in addition to the peak detector 425. The Fast Fourier Transform unit 426 may also be provided instead of the peak detector 425. In such embodiments, the Fast Fourier Transform unit 426 may determine the amplitude of the incoming signal 403.

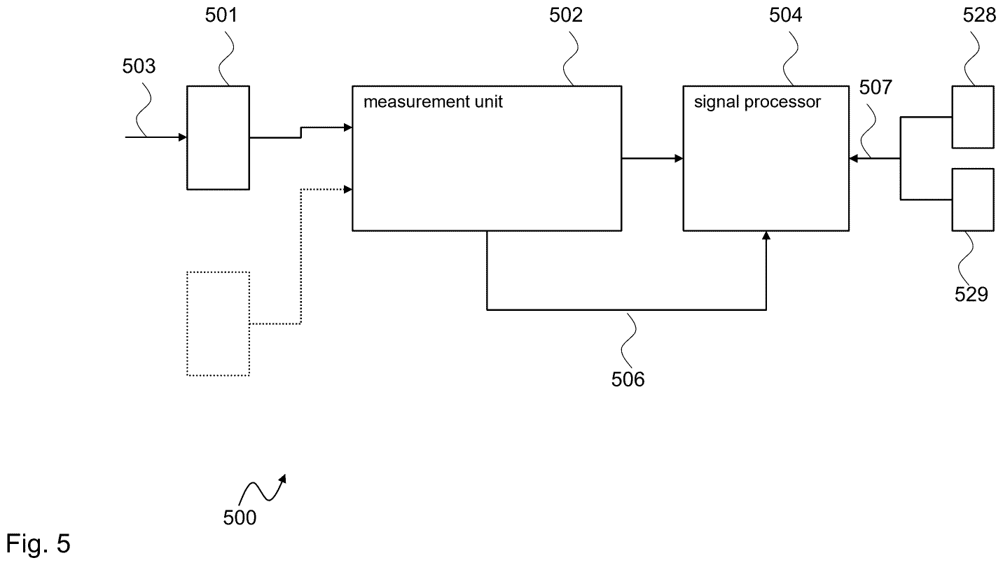

FIG. 5 shows a measurement application device 500. The measurement application device 500 is based on the measurement application device 100. Therefore, the measurement application device 500 comprises a signal port 501 that is coupled to a measurement unit 502. More possible signal ports that may be coupled to the measurement unit 502 are hinted at by a dotted signal port. The measurement unit 502 is coupled to a signal processor 504. The signal port 501 serves for receiving an incoming signal 503 that is to be analyzed. The explanations provided herein for any of the embodiments of the measurement application device apply mutatis mutandis to the measurement application device 500.

The measurement application device 500 further comprises a user interface 528 that is coupled to signal processor 504. Further, the measurement application device 500 comprises a control interface 529 that is also coupled to the signal processor 504. The user interface 528, and the control interface 529 both serve for providing the maximum and/or minimum signal levels to be measured 507 to the signal processor 504.

The user interface 528 may be integrated into the measurement application device 500. Such a user interface 528 may comprise e.g., buttons, knobs, touchscreen devices or the like. The user interface 528 may also be provided as a remote user interface that may be accessed e.g., as a website via a browser application or a dedicated application that may be executed on a user device.

The control interface 529 may be a digital interface, like a network interface or a digital data bus interface that may receive and send control data to or from other devices. With the control interface 529 the measurement application device 500 may easily be integrated into (semi-) automated measurement setups.

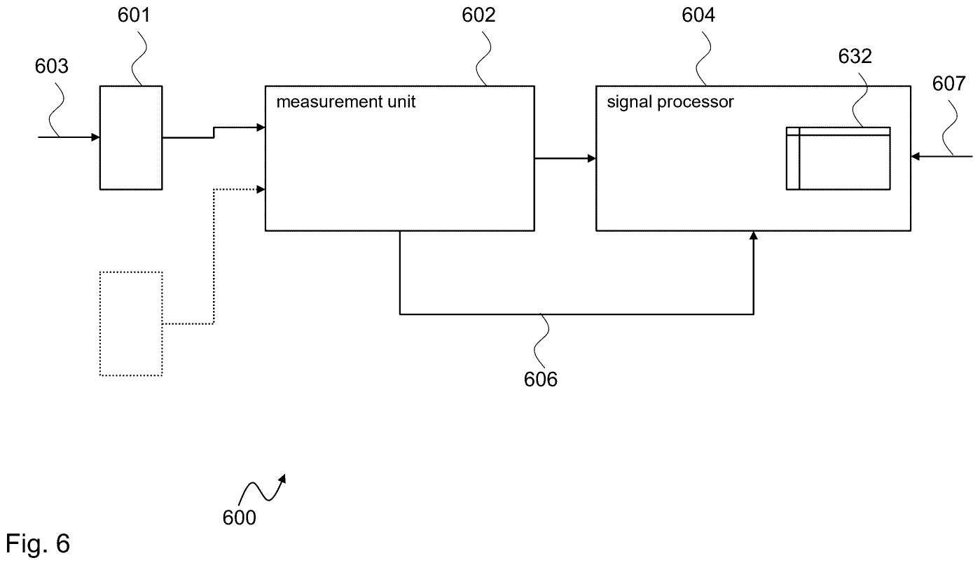

FIG. 6 shows a measurement application device 600. The measurement application device 600 is based on the measurement application device 100. Therefore, the measurement application device 600 comprises a signal port 601 that is coupled to a measurement unit 602. More possible signal ports that may be coupled to the measurement unit 602 are hinted at by a dotted signal port. The measurement unit 602 is coupled to a signal processor 604. The signal port 601 serves for receiving an incoming signal 603 that is to be analyzed. The explanations provided herein for any of the embodiments of the measurement application device apply mutatis mutandis to the measurement application device 600.

In the measurement application device 600, the signal processor 604 comprises a look-up table 632. The look-up table 632 serves for the signal processor 604 to map the maximum and/or minimum signal levels to be measured 607 to a respective resolution and/or video bandwidth 606.

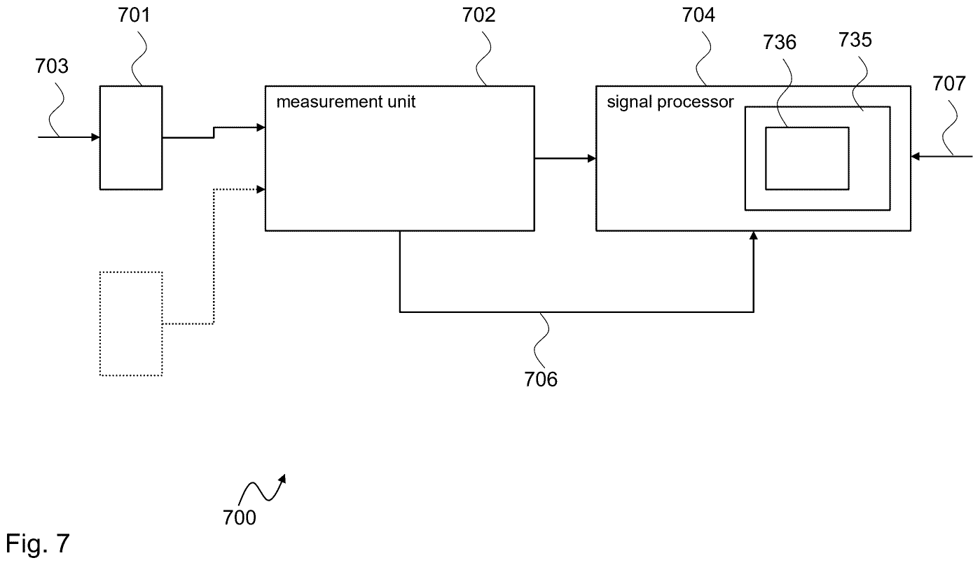

FIG. 7 shows a measurement application device 700. The measurement application device 700 is based on the measurement application device 100 and shows an alternative to the measurement application device 600. In embodiments, the look-up table 632 of the measurement application device 600 may be combined with the features of the measurement application device 700. The measurement application device 700 comprises a signal port 701 that is coupled to a measurement unit 702. More possible signal ports that may be coupled to the measurement unit 702 are hinted at by a dotted signal port. The measurement unit 702 is coupled to a signal processor 704. The signal port 701 serves for receiving an incoming signal 703 that is to be analyzed. The explanations provided herein for any of the embodiments of the measurement application device apply mutatis mutandis to the measurement application device 700.

In the measurement application device 700, the signal processor 704 comprises a processing unit 735 that executes a determination algorithm 736. The determination algorithm 736 may be any kind of algorithm that receives at least the maximum and/or minimum signal levels to be measured 707 and calculates the resolution and/or video bandwidth 706 based on the received maximum and/or minimum signal levels to be measured 707.

In embodiments, the determination algorithm 736 may comprise an artificial-intelligence-based algorithm that may be pre-trained to determine the resolution and/or video bandwidth 706.

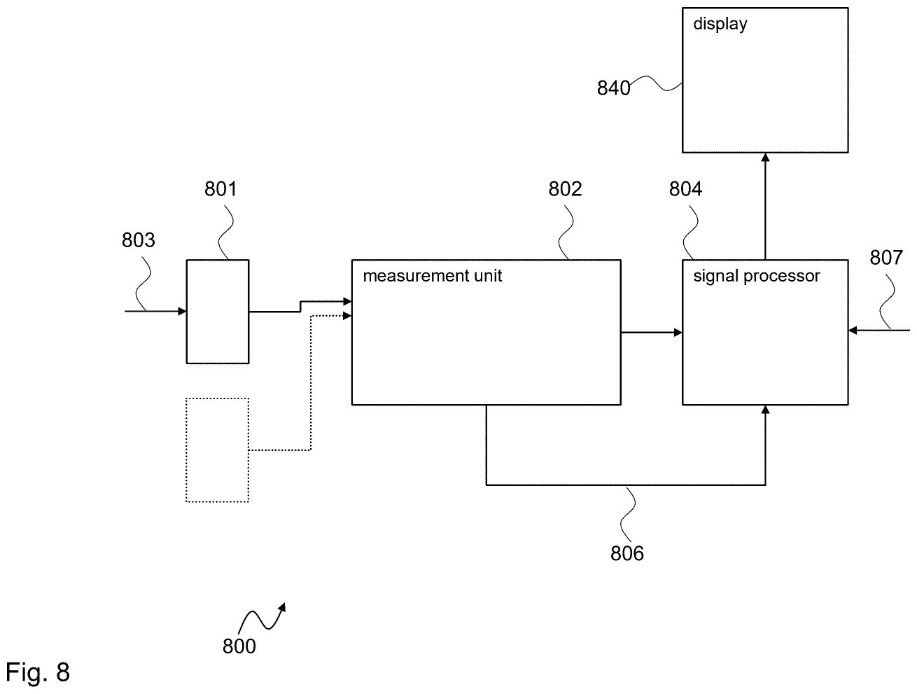

FIG. 8 shows a measurement application device 800. The measurement application device 800 is based on the measurement application device 100. Therefore, the measurement application device 800 comprises a signal port 801 that is coupled to a measurement unit 802. More possible signal ports that may be coupled to the measurement unit 802 are hinted at by a dotted signal port. The measurement unit 802 is coupled to a signal processor 804. The signal port 801 serves for receiving an incoming signal 803 that is to be analyzed. The explanations provided herein for any of the embodiments of the measurement application device apply mutatis mutandis to the measurement application device 800.

The measurement application device 800 further comprises a display 840 that is coupled to the signal processor 804. The display 840 serves for displaying to a user the determined resolution and/or video bandwidth 806, especially for multiple frequencies or frequency ranges. Further, the display 840 may also show the incoming signal 803 or the result of the processing of the incoming signal 803 by the measurement unit 802.

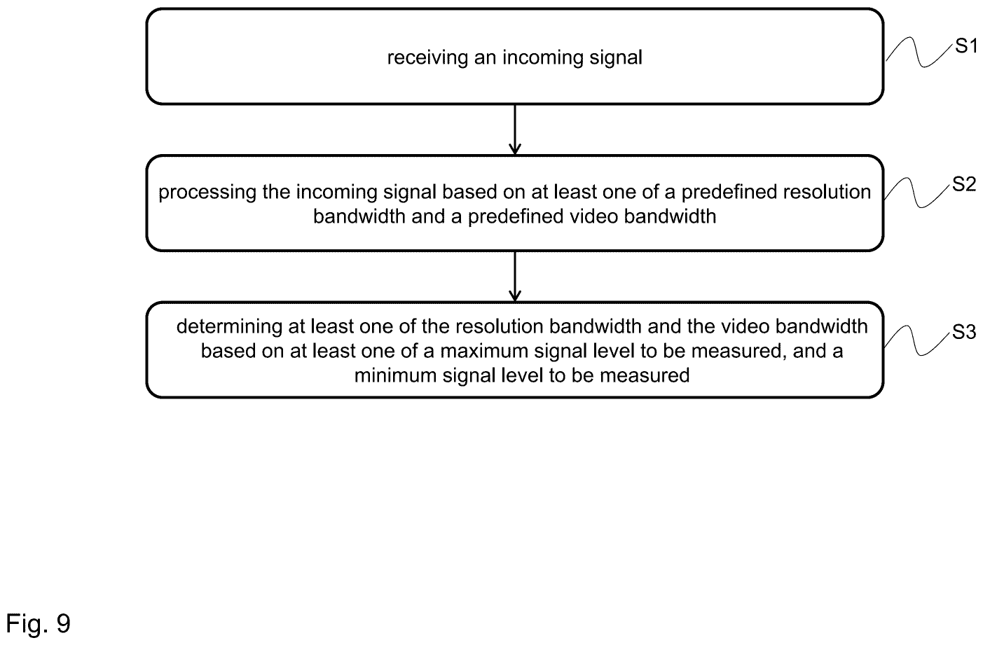

FIG. 9 shows a flow diagram of a method for operating a measurement application device according to the present disclosure.

The method comprises receiving S1 an incoming signal, processing S2 the incoming signal based on at least one of a predefined resolution bandwidth and a predefined video bandwidth, and determining S3 at least one of the resolution bandwidth and the video bandwidth based on at least one of a maximum signal level to be measured, and a minimum signal level to be measured.

The method may further comprise determining at least one of the maximum signal level to be measured, and the minimum signal level to be measured based on a signal amplitude of the incoming signal. The at least one of the maximum signal level to be measured, and the minimum signal level to be measured may further determined based on a signal level of a local oscillator signal used for processing the incoming signal.

As indicated above the at least one of the maximum signal level to be measured, and the minimum signal level to be measured may exemplarily be determined with a look-up table, or a respective algorithm, especially an artificial intelligence algorithm.

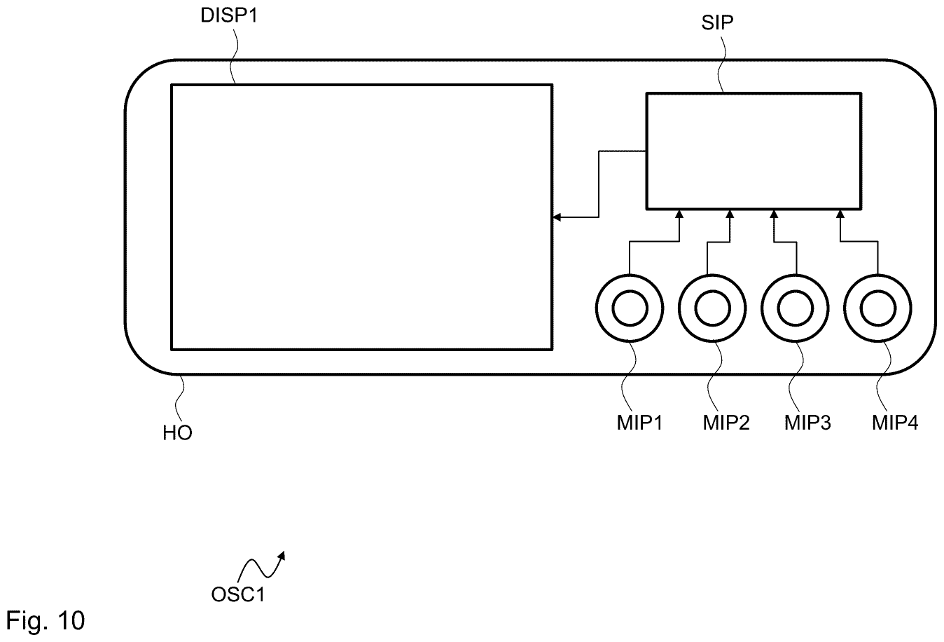

FIG. 10 shows a block diagram of an oscilloscope OSC1 that may be used with an embodiment of a measurement application device according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the signal processor SIP or an additional processing element may perform the function of the signal processor and processing elements of the measurement unit according to the present disclosure, or may implement the method according to the present disclosure. Of course, a communication interface may be provided in the oscilloscope OSC1 for communication with other measurement application devices.

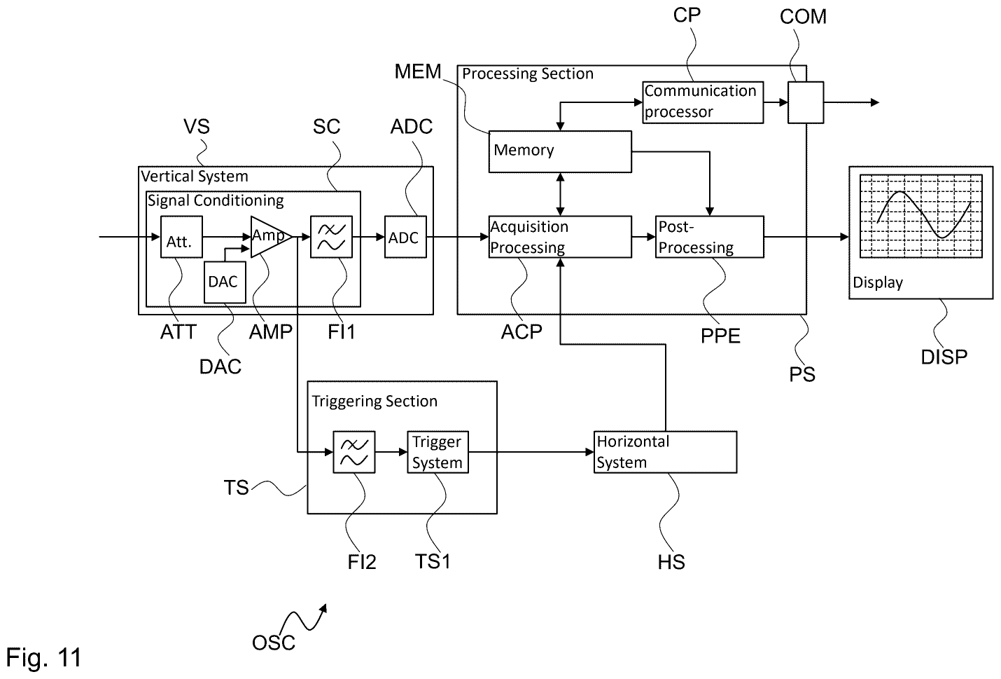

FIG. 11 shows a block diagram of an oscilloscope OSC that may be an implementation of a measurement application device according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood, that the partitioning into five general sections is a logical partitioning and does not limit the placement and implementation of any of the elements of the oscilloscope OSC in any way.

The vertical system VS mainly serves for offsetting, attenuating and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP. The amplifier AMP is coupled to a filter FI1, which in the shown example is provided as a low pass filter. The vertical system VS also comprises an analog-to-digital converter ADC that receives the output from the filter FI1 and converts the received analog signal into a digital signal.

The attenuator ATT and the amplifier AMP serve to scale the amplitude of the signal to be acquired to match the operation range of the analog-to-digital converter ADC. The digital-to-analog-converter DAC serves to modify the DC component of the input signal to be acquired to match the operation range of the analog-to-digital converter ADC. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC and the output of the horizontal system HS as well as to a memory MEM and a post processing element PPE.

The acquisition processing element ACP manages the acquisition of digital data from the analog-to-digital converter ADC and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

In the oscilloscope OSC, any one of the processing elements in the processing section PS or an additional processing element may perform the function of the signal processor or the processing element of the measurement unit according to the present disclosure.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100 measurement application device
101 signal port
102 measurement unit
103 incoming signal
104 signal processor
106 resolution bandwidth/video bandwidth
107 maximum signal level/minimum signal level
315 input port
316 attenuator
317 local oscillator
318 mixer
319 filter
320 signal analyzer
321 amplitude
425 peak detector
426 Fast Fourier Transformation unit
528 user input interface
529 control interface
632 look-up table
735 processing unit
736 determination algorithm
840 display
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP amplifier
FI1 filter
DAC digital-to-analog converter
ADC analog-to-digital converter
TS triggering section
AMP2 amplifier
FI2 filter
TS1 trigger system
HS horizontal system
PS processing section
ACP acquisition processing element
MEM memory
PPE post processing element
DISP display

What is claimed is:

1. A measurement application device comprising:
at least one signal port;
at least one measurement unit coupled to the at least one signal port, wherein the at least one measurement unit is configured to process an incoming signal received via the at least one signal port based on at least one of a predefined resolution bandwidth and a predefined video bandwidth; and
a signal processor coupled to the at least one measurement unit;
wherein the signal processor is configured to determine at least one of the resolution bandwidth and the video bandwidth for the at least one measurement unit based on at least one of:
a maximum signal level to be measured; and
a minimum signal level to be measured.

2. The measurement application device according to claim 1, wherein the at least one measurement unit comprises:
at least one input port, each input port being coupled to one signal port;
an attenuator for each input port, wherein the attenuator is coupled to the respective input port;
a local oscillator;
a mixer for each attenuator, wherein the mixer is coupled to the local oscillator and the respective attenuator;
a filter for each mixer, wherein the filter is coupled to the respective mixer; and
a signal analyzer for each filter, wherein the signal analyzer is coupled to the respective filter, and wherein the signal analyzer is configured to determine at least an amplitude of the respective incoming signal, and to provide the determined amplitude to the signal processor.

3. The measurement application device according to claim 2, wherein the signal processor is further configured to determine at least one of a maximum signal level to be measured and a minimum signal level to be measured based on the determined signal amplitude.

4. The measurement application device according to claim 2, wherein the signal processor is further configured to determine at least one of a maximum signal level to be measured and a minimum signal level to be measured, based further on a signal level of a signal provided by the local oscillator.

5. The measurement application device according to claim 2, wherein the signal processor is further configured to set a signal level of a signal provided by the local oscillator based on a predetermined spurious free dynamic range for the mixer.

6. The measurement application device according to claim 2, wherein the signal processor is further configured to set a filter bandwidth for the filter in order to set the at least one of the resolution bandwidth and the video bandwidth.

7. The measurement application device according to claim 2, wherein the signal analyzer comprises at least one of a peak detector and a Fast Fourier Transformation unit.

8. The measurement application device according to claim 7, wherein the signal processor is further configured to set a bandwidth for the Fast Fourier Transformation unit in order to set the at least one of the resolution bandwidth and the video bandwidth.

9. The measurement application device according to claim 2, wherein the signal processor is further configured to set an attenuation level of the attenuator in order to set the at least one of the resolution bandwidth and the video bandwidth.

10. The measurement application device according to claim 1, wherein the signal processor is configured to determine the at least one of the resolution bandwidth and the video bandwidth such that the measurement time is minimized.

11. The measurement application device according to claim 1, further comprising at least one of a user input interface and a control interface, wherein the at least one of the user input interface and the control interface is configured to receive at least one of the maximum signal level and the minimum signal level, and to forward the received at least one of the maximum signal level and the minimum signal level to the signal processor.

12. The measurement application device according to claim 1, wherein the signal processor comprises a look-up table that maps the at least one of the maximum signal level and the minimum signal level to at least one of the resolution bandwidth and the video bandwidth.

13. The measurement application device according to claim 1, wherein the signal processor comprises a processing unit configured to execute a determination algorithm that determines at least one of the resolution bandwidth and the video bandwidth for the at least one of the maximum signal level and the minimum signal level.

14. The measurement application device according to claim 13, wherein the determination algorithm comprises an artificial-intelligence-based algorithm.

15. The measurement application device according to claim 1, wherein the signal processor is further configured to receive a plurality of sets comprising at least one of a maximum signal level to be measured and a minimum signal level to be measured for a specific frequency range; and
wherein the signal processor is further configured to determine the at least one of the resolution bandwidth and the video bandwidth for each set based on the at least one of a maximum signal level to be measured and a minimum signal level to be measured provided in the respective set.

16. The measurement application device according to claim 1, further comprising a display coupled to the signal processor, wherein the signal processor is configured to display at least one of different resolution bandwidths and different video bandwidths for different frequency ranges.

17. The measurement application device according to claim 1, wherein the signal processor is further configured to receive an indication of a signal type of the incoming signal; and
wherein the signal processor is further configured to automatically determine the at least one of the resolution bandwidth and the video bandwidth for different frequency ranges based on the signal type.

18. The measurement application device according to claim 17, wherein the signal processor is further configured to determine the signal type of the incoming signal, and use the determined signal type as received indication of the signal type.

19. A method for operating a measurement application device, the method comprising:
receiving an incoming signal;
processing the incoming signal based on at least one of a predefined resolution bandwidth and a predefined video bandwidth; and
determining at least one of the resolution bandwidth and the video bandwidth based on at least one of:
a maximum signal level to be measured; and
a minimum signal level to be measured.

20. The method according to claim 19, further comprising determining at least one of the maximum signal level to be measured, and the minimum signal level to be measured based on a signal amplitude of the incoming signal.

21. The method according to claim 19, wherein the at least one of the maximum signal level to be measured, and the minimum signal level to be measured are further determined based on a signal level of a local oscillator signal used for processing the incoming signal.
